(19) United States
(12) Patent Application Publication
(10) Pub. No.: US 2025/0253224 A1
(43) Pub. Date: Aug. 7, 2025

(54) ADVANCED ACTIVE POWER DISTRIBUTION NETWORK (PDN) INTEGRATION

(71) Applicant: QUALCOMM Incorporated, San Diego, CA (US)

(72) Inventors: Xia LI, San Diego, CA (US); Kai LIU, San Diego, CA (US); Bin YANG, San Diego, CA (US)

(21) Appl. No.: 18/431,854

(22) Filed: Feb. 2, 2024

(51) Int. Cl. H01L 23/498; H01L 23/00; H01L 25/065

(52) U.S. Cl. CPC H01L 23/49838; H01L 23/49816; H01L 24/08; H01L 24/16; H01L 25/0652; H01L 2224/08146; H01L 2224/08155; H01L 2224/16146; H01L 2224/16157; H01L 2924/01029; H01L 2924/14252; H01L 2924/1431; H01L 2924/1434; H01L 2924/15311

(57) ABSTRACT

An integrated circuit (IC) including a die is described. The die is composed of an active device layer and interconnect layers coupled to the active device layer. The IC also includes an active power distribution network (PDN) layer. The active PDN layer includes a power switch and an intermetal dielectric (IMD) layer. The IMD metal layer is coupled between the power switch and the die.

### BACKGROUND

### Field

Aspects of the present disclosure relate to integrated circuits (ICs) and, more particularly, to an advanced active power distribution network (PDN) integration.

### Background

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has increased due to the substantial number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to power routing issues when a power management integrated circuit (PMIC) is outside of a system-on-chip (SoC) and on a printed circuit board (PCB). In this arrangement, a passive power distribution network (PDN) may exhibit a substantial PDN current (I) resistance (R) (IR) drop (e.g., ˜+64 mV). Additionally, this passive PDN consumes an input energy power (e.g., ˜1×) resulting in a further IR drop (e.g., ˜1×). As a result, implementing a passive PDN in combination with an outside PMIC on the PCB involves a higher minimum voltage (Vmin) to compensate for the voltage drops.

### SUMMARY

An integrated circuit (IC) including a die is described. The die is composed of an active device layer and interconnect layers coupled to the active device layer. The IC also includes an active power distribution network (PDN) layer. The active PDN layer includes a power switch and an intermetal dielectric (IMD) layer. The IMD metal layer is coupled between the power switch and the die.

A method for fabricating an integrated circuit (IC) having an active power distribution network (PDN) layer is described. The method includes forming a die. The die includes an active device layer and interconnect layers coupled to the active device layer. The method also includes forming the active power distribution network (PDN) layer. The PDN layer includes a power switch and an intermetal dielectric (IMD) layer. The IMD layer is coupled between the power switch and the die.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-chip (SoC), including an advanced active power distribution network (PDN) integration, in accordance with certain aspects of the present disclosure.

FIG. 2 shows a cross-sectional view of a stacked integrated circuit (IC) package, of the host system-on-chip (SoC) of FIG. 1.

FIG. 3 shows a cross-sectional view illustrating the stacked integrated circuit (IC) package of FIG. 2, incorporated into a wireless device, according to one aspect of the present disclosure.

FIGS. 4A and 4B are block diagrams illustrating cross-sectional views of an integrated circuit (IC) having an active power distribution network (PDN) integrated in a die, according to various aspects of the present disclosure.

FIG. 5 is a block diagram illustrating a cross-sectional view of an integrated circuit (IC) having a backside power rail active power distribution network (PDN) integrated in a die, according to various aspects of the present disclosure.

FIG. 6 is a block diagram illustrating a cross-sectional view of an integrated circuit (IC) having a backside power rail active power distribution network (PDN) integrated in a die, according to various aspects of the present disclosure.

FIGS. 7A-7L are cross-sectional diagrams illustrating a process for fabricating the integrated circuit (IC) of FIG. 5, having the backside power rail active power distribution network (PDN) integrated in the die, according to various aspects of the present disclosure.

FIG. 8 is a process flow diagram illustrating a method for fabricating an active power distribution network (PDN), according to various aspects of the present disclosure.

FIG. 9 is a block diagram showing an exemplary wireless communications system, in which an aspect of the present disclosure may be advantageously employed.

FIG. 10 is a block diagram illustrating a design workstation used for circuit, layout, and logic design of a semiconductor component such as the advanced active power distribution network (PDN) disclosed herein.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

A system hierarchy includes interconnection of active devices at a lowest system level all the way up to system level interconnections at a highest level. In particular, electrical connections exist at each of the levels of the system hierarchy to connect different devices together on an integrated circuit (IC). As integrated circuits become more complex, however, more interconnect layers are used to provide the electrical connections between the devices. More recently, the number of interconnect levels for circuitry has increased due to the substantial number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an integrated circuit (IC). The various BEOL interconnect layers are formed at corresponding BEOL interconnect levels, in which lower BEOL interconnect levels use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. Stacked die schemes and chiplet architectures are becoming mainstream as significant power performance area (PPA) yield enhancements are demonstrated for stacked die and chiplet architecture product lines. Unfortunately, successful stacked die schemes involve high power density targets, which impose significant power distribution losses.

In particular, these mobile applications are susceptible to power routing issues when a power management integrated circuit (PMIC) is outside of a system-on-chip (SoC) and on a printed circuit board (PCB). In this arrangement, a passive power distribution network (PDN) may exhibit a substantial PDN current (I) resistance (R) (IR) drop (e.g., ˜+64 mV). This arrangement is further degraded when implementing a power head switch at a front-end-of-line (FEOL) device due to a substantial extension of a power rail path (e.g., 3 times (3×) longer). Additionally, a passive PDN consumes an input energy power (e.g., ˜1×) resulting in a further IR drop (e.g., ˜1×). As a result, implementing a passive PDN in combination with an outside PMIC on the PCB involves a higher minimum voltage (Vmin) to compensate for the voltage drops.

Various aspects of the present disclosure provide an advanced active power distribution network (PDN) integration. The process flow for fabrication of the advanced active power distribution network (PDN) integration may further include an advanced backside power rail active PDN integration. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably. Similarly, the terms “chip,” “chiplet,” and “die” may be used interchangeably.

Aspects of the present disclosure are directed to advanced active power distribution network (PDN) integration. In some aspects of the present disclosure, implementation of the advanced active PDN integration involves integrating a power switch in interconnect layers at a frontside or backside of a die. In this configuration, the die is composed of an active device layer and interconnect layers coupled to the active device layer. Additionally, an active power distribution network (PDN) layer, including a power switch and an intermetal dielectric (IMD) metal layer. In various aspects of the present disclosure, the IMD metal layer is coupled between the power switch and the die at a frontside or a backside of the die.

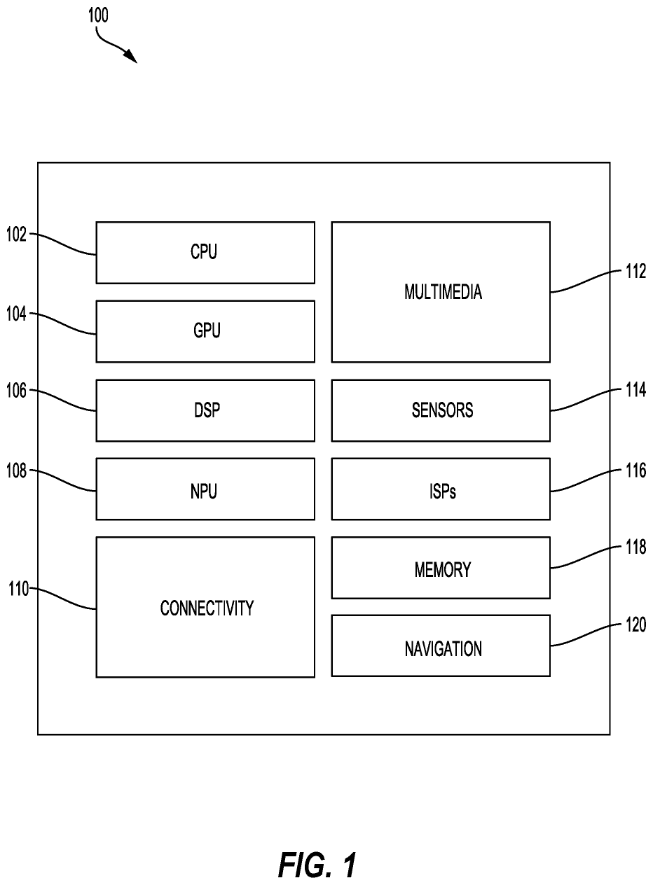

FIG. 1 illustrates an example implementation of a host system-on-chip (SoC) 100, which includes an advanced active power distribution network (PDN) integration, in accordance with certain aspects of the present disclosure. The host SoC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

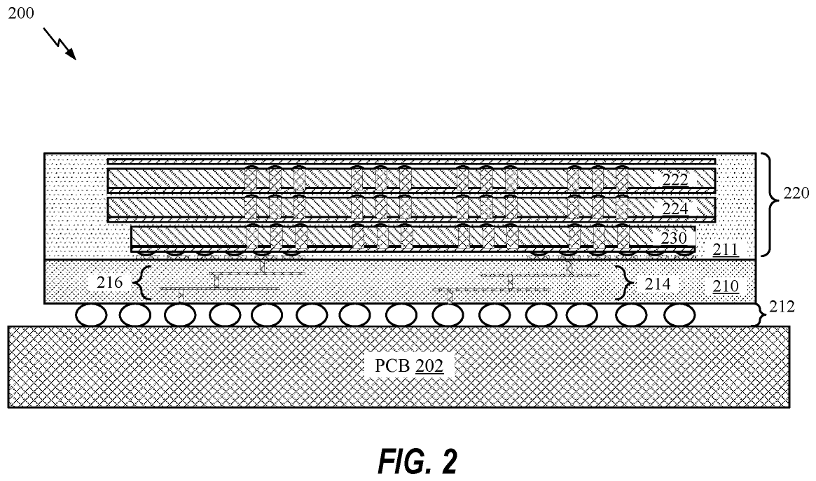

FIG. 2 shows a cross-sectional view of a stacked integrated circuit (IC) package 200 of the host system-on-chip (SoC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the host SoC 100 of FIG. 1.

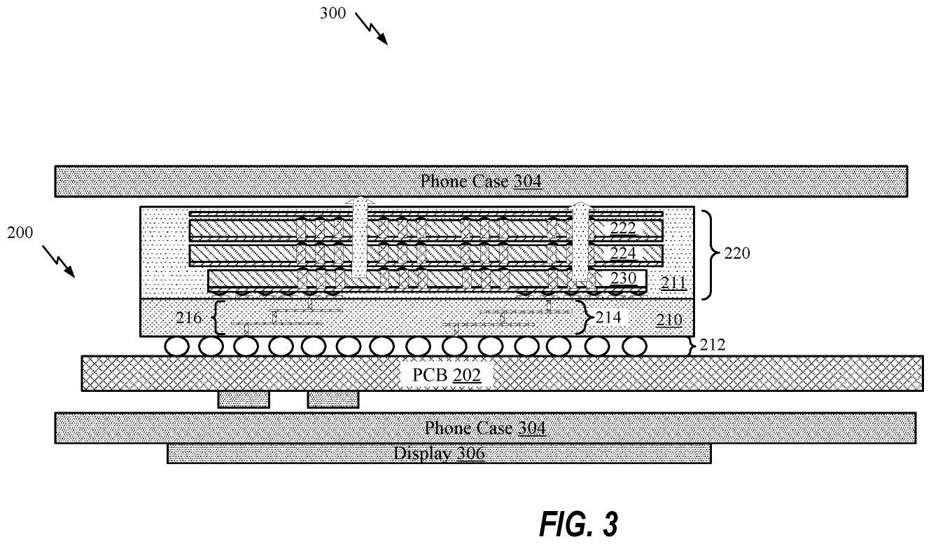

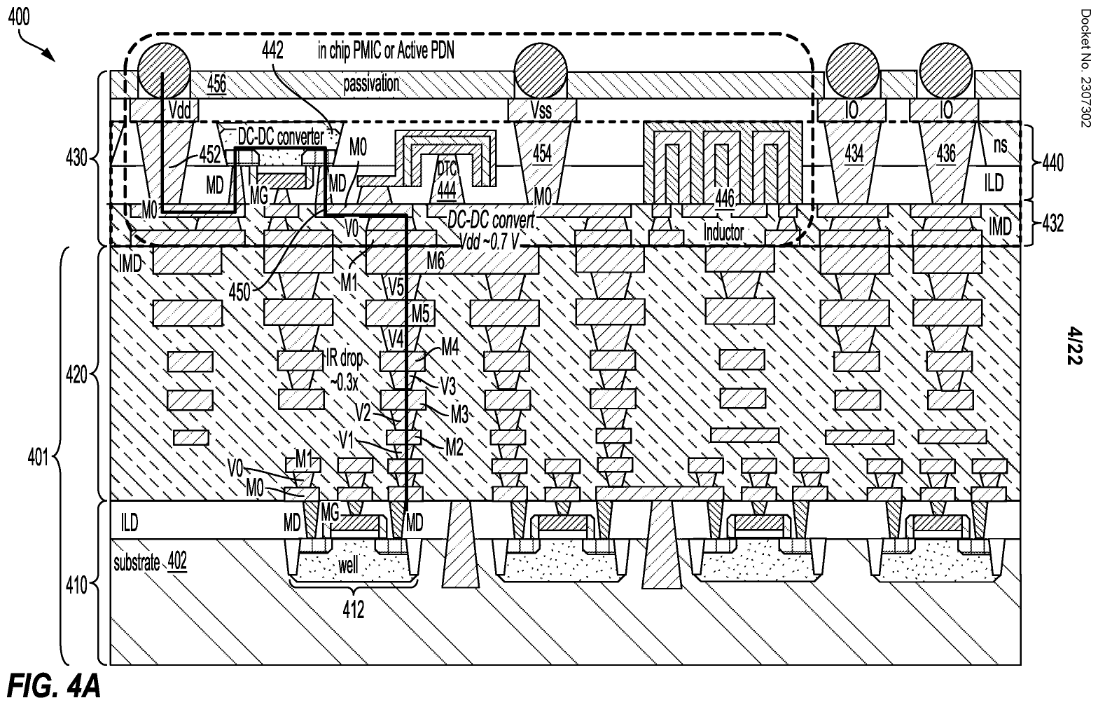

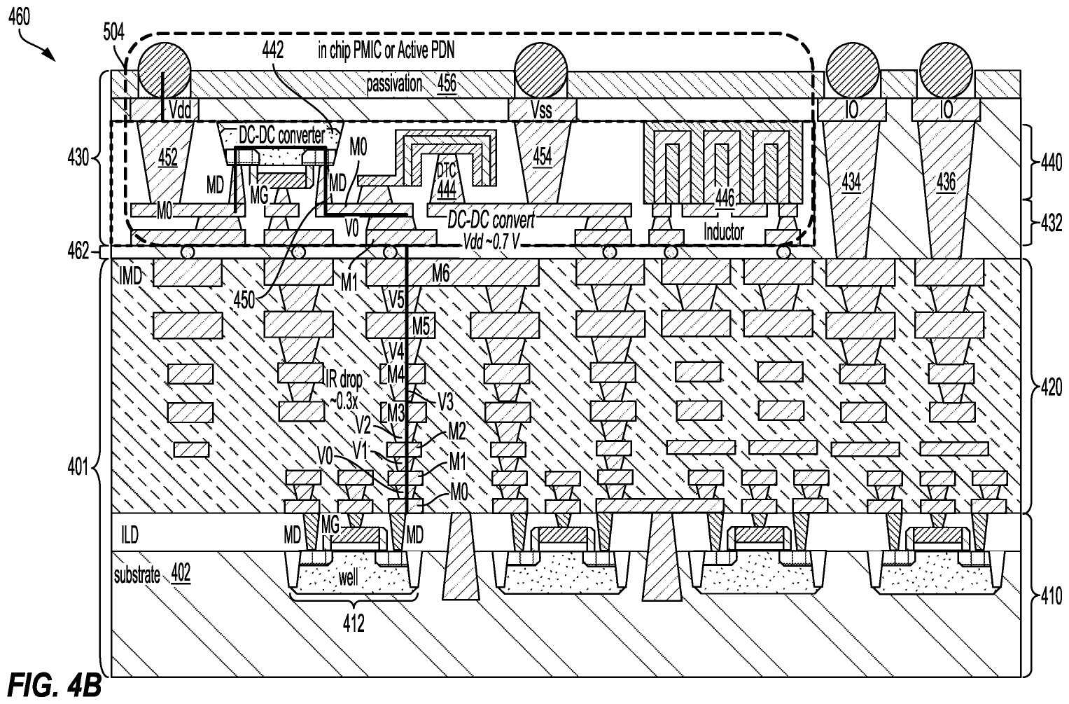

FIG. 3 shows a cross-sectional view illustrating the stacked integrated circuit (IC) package 200 of FIG. 2, incorporated into a wireless device 300, according to one aspect of the present disclosure. As described, the wireless device 300 may include, but is not limited to, a smartphone, tablet, handheld device, or other limited form factor device configured for 5G NR/6G communications. Representatively, the stacked IC package 200 is within a phone case 304, including a display 306. In this configuration, an advanced active power distribution network (PDN) is integrated in the stacked IC package 200, for example, as shown in FIGS. 4A to 7L.

FIGS. 4A and 4B are block diagrams illustrating cross-sectional views of an integrated circuit (IC) 400 having an active power distribution network (PDN) integrated in a die, according to various aspects of the present disclosure. As shown in FIG. 4A, the IC 400 includes a die 401, having an active device layer 410 and an interconnect layer 420 coupled to active devices 412 in a substrate 402 of the active device layer 410. In this example, the interconnect layer 420 includes middle-of-line (MOL) layers (M0, V0) coupled to the active devices 412 through metal-to-diffusion (MD) contacts and metal-to-gate (MG) contacts. Additionally, the interconnect layer 420 includes back-end-of-line (BEOL) metal layers (e.g., M1, V1, M2, V2, M3, V3, M4, V4, M5, V5, M6) coupled to the active devices 412 through the MOL layers (e.g., M0, V0), and the contacts (e.g., MD, MG).

As shown in FIG. 4A, an active power distribution network (PDN) 430 is integrated with the interconnect layer 420 on a frontside of the die 401. In this example, the active PDN 430 includes an intermetal dielectric (IMD) layer 432 on a device layer 440. Additionally, the active PDN 430 is bonded to the frontside of the die 401 using, for example, a metal to metal (e.g., copper Cu) hybrid bonding of a first metal (M1) layer of the IMD layer 432 and an M6 metal layer of the interconnect layer 420 at the backside of the die 401. In this example, an IO via interconnect 434 and an IO interconnect 436 extend through the device layer 440 of the active PDN 430 and couple IO pads supporting IO balls to zero metal (M0) layers of the IMD layer 432.

According to various aspects of the present disclosure, the active PDN 430 operates as a power stage to provide a direct current (DC) to a DC (DC-DC) converter for supplying a DC output voltage (e.g., =0.7 volts (V)) to power the die 401 through a power rail path 450. This configuration of the active PDN 430 includes the device layer 440, which is composed of a power switch 442, a deep trench capacitor (DTC) 444, and an inductor 446 (e.g., a magnetic inductor). Additionally, a via interconnect 452 extends through the device layer 440 of the active PDN 430 and couples a Vdd power rail pad supporting a Vdd ball to a zero metal (M0) layer of the IMD layer 432.

In various aspects of the present disclosure, the power rail path 450 extends from the Vdd ball through a Vdd pad, the via interconnect 452, the M0 metal layer, and the MD contact to the power switch 442 of the IMD layer 432 of the active PDN 430 on a backside of the die 401. The power rail path 450 proceeds through the MD contact, the MOL layers M0 and V0 of the IMD layer 432 through the interconnect layer 420 of the die 401 to the active devices 412. Additionally, a ground rail Vss ball is coupled to the DTC 444 through a Vss pad, a via interconnect 454, and an M0 metal layer. A passivation layer 456 is deposited on a surface of the active PDN 430.

In various aspects of the present disclosure, the active PDN 430 (or PMIC) of the IC 400 is integrated at the upper portion of the interconnect layer 420 (e.g., M6 metal layer BEOL) of the die 401, which increases (e.g., 1×) the power rail path 450. Additionally, the active PDN 430 provides a DC-DC converter using the power switch 442 and the DTC 444 to provide a decoupling capacitor for supporting a higher (e.g., ˜5×˜20×) input power energy in the IC 400. Because this configuration of the IC 400 exhibits a reduced current (I) resistance (R) (IR) drop (e.g., ˜0.3×), the IC 400 may be configured to operate using a lower minimum voltage (Vmin) due to the reduced IR drop and large decoupling capacitance provided by the DTC 444.

As shown in FIG. 4B, an integrated circuit (IC) 460 is similar to the IC 400 shown in FIG. 4A and is described using similar reference numbers. In this example, the IC 460 also includes the die 401, having the active device layer 410 and the interconnect layer 420 coupled to active devices 412 in the substrate 402 of the active device layer 410. As shown in FIG. 4B, the active PDN 430 is also integrated with the interconnect layer 420 on the frontside of the die 401. In this example, the active PDN 430 includes the IMD layer 432 on the device layer 440. Additionally, the active PDN 430 is coupled to the frontside of the die 401 using micro-bumps 462 coupled between the M1 metal layer of the IMD layer 432 and the M6 metal layer of the interconnect layer 420 at the frontside of the die 401.

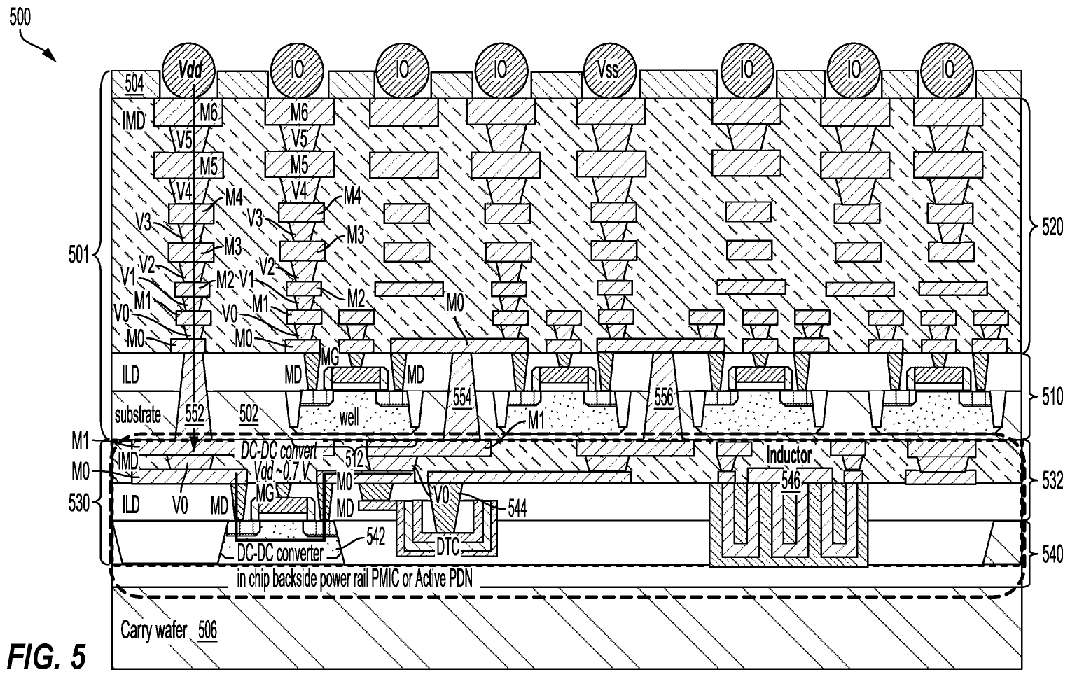

FIG. 5 is a block diagram illustrating a cross-sectional view of an integrated circuit (IC) 500 having a backside power rail active power distribution network (PDN) integrated in a die, according to various aspects of the present disclosure. As shown in FIG. 5, the IC 500 includes a die 501, having an active device layer 510 and an interconnect layer 520 coupled to active devices 512 in a substrate 502 of the active device layer 510. In this example, the interconnect layer 520 includes middle-of-line (MOL) layers (M0, V0) coupled to the active devices 512 through metal-to-diffusion (MD) contacts and metal-to-gate (MG) contacts. Additionally, the interconnect layer 520 includes back-end-of-line (BEOL) metal layers (e.g., M1, V1, M2, V2, M3, V3, M4, V4, M5, V5, M6) coupled to the active devices 512 through the MOL layers (e.g., M0, V0), and the contacts (e.g., MD, MG).

As shown in FIG. 5, the IC 500 includes a backside power rail active power distribution network (PDN) 530 integrated with a backside of the die 501. In this example, the backside power rail active PDN 530 includes an intermetal dielectric (IMD) layer 532 on a device layer 540. The IMD layer 532 of the backside power rail active PDN 530 is contacted to the die 501 using the lower portion of the interconnect layer 520 (e.g., M1 metal layer BEOL) and a via interconnect 552 through the active device layer 510 of the die 501, which reduces the IR drop (e.g., 0.1×) of a power rail path 550. In various aspects of the present disclosure, a smart cut thin layer transfer (TLT) and hydrogen (e.g., O—H) bonding integration of the backside power rail active PDN 530 is performed. This process is followed by securing a carrier wafer 506 to a backside of the backside power rail active PDN 530.

Additionally, the backside power rail active PDN 530 is bonded to the backside of the die 501 using, for example, a smart cut thin layer transfer (TLT) and hydrogen (e.g., O—H) bonding integration of the IMD layer 532 of the backside power rail active PDN 530 and the backside to the die 501. In this example, an M1 metal layer of the IMD layer 532 of the backside power rail active PDN 530 is contacted to the backside of the die 501 using the lower portion of the interconnect layer 520 (e.g., M0 metal layer) and the via interconnect 552 through the active device layer 510 of the die 501. In this example, a via interconnect 554 and a via interconnect 556 extend through the device layer 540 of the backside power rail active PDN 530 and couple M1 metal layers to zero metal (M0) layers of the IMD layer 532.

According to various aspects of the present disclosure, the backside power rail active PDN 530 operates as a power stage to provide direct current (DC) to DC (DC-DC) conversion for supplying a DC output voltage (e.g., =0.7 volts (V)) to power the die 501 through the power rail path 550. This configuration of the backside power rail active PDN 530 includes the device layer 540, which is composed of a power switch 542, a deep trench capacitor (DTC) 544, and an inductor 546 (e.g., a magnetic inductor). In various aspects of the present disclosure, the power rail path 550 extends from a Vdd ball in a passivation layer 504, through the interconnect layer 520, the via interconnect 552, the IMD layer 532, and the MD contact to the power switch 542. The power rail path 550 proceeds through the MD contact, the MOL layers M0 and V0 of the IMD layer 532 through the via interconnect 554 to the interconnect layer 520 of the die 501 and to the active devices 512.

In various aspects of the present disclosure, the backside power rail active PDN 530 (or PMIC) is integrated at the backside power rail of an SoC implemented from the IC 500, which provides a substantial PDN IR drop (e.g., −64 mV). The IMD layer 532 of the backside power rail active PDN 530 is contacted to the die 501 using the lower portion of the interconnect layer 520 (e.g., M0 metal layer) and the via interconnect 552 through the active device layer 510 of the die 501, which reduces the IR drop (e.g., 0.1×) of the power rail path 550. In various aspects of the present disclosure, a smart cut thin layer transfer (TLT) and hydrogen (e.g., O—H) bonding is performed to integrate the backside power rail active PDN 530 on the backside of the die. Additionally, the backside power rail active PDN 530 provides DC-DC conversion using the power switch 542 and the DTC 544 to provide a decoupling capacitor for supporting a higher (e.g., ˜5× to ˜20×) input power energy in the IC 500. Because this configuration of the IC 500 exhibits a reduced IR drop (e.g., ˜0.3×), the IC 500 operates with a lower minimum voltage (Vmin) due to the reduced IR drop and large decoupling capacitance provided by the DTC 444, which consumes less power while providing high performance.

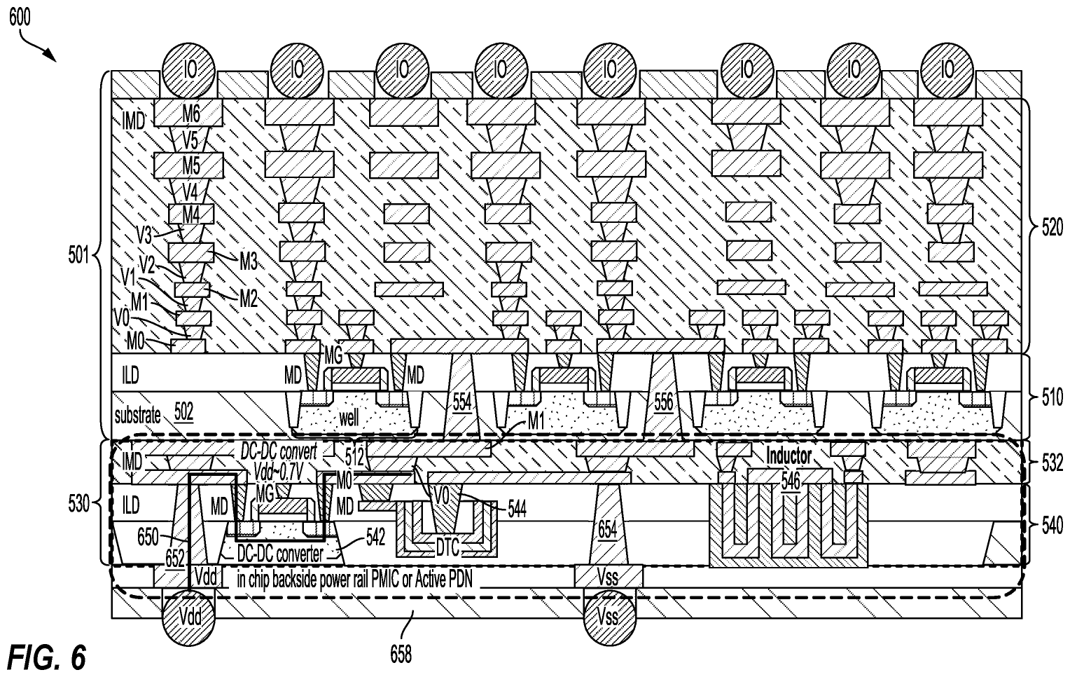

FIG. 6 is a block diagram illustrating a cross-sectional view of an integrated circuit (IC) 600 having a backside power rail active power distribution network (PDN) integrated in a die, according to various aspects of the present disclosure. As shown in FIG. 6, the IC 600 is similar to the IC 500 shown in FIG. 5 and is described using similar reference numbers. In this example, the IC 600 also includes the die 501, having the active device layer 510 and the interconnect layer 520 coupled to active devices 512 in the substrate 502 of the active device layer 510. As shown in FIG. 6, the backside power rail active PDN 530 is also integrated with the interconnect layer 520 on the backside of the die 501 through the via interconnect 554 and the via interconnect 556. In this configuration, a via interconnect 652 extends through the device layer 540 of the backside power rail active PDN 530 and couples a Vdd pad supporting a Vdd ball to a M0 metal layer of the IMD layer 532. Additionally, a ground rail Vss ball is coupled to the DTC 544 through a Vss pad, a via interconnect 654, and an M0 metal layer. A passivation layer 658 is deposited on a surface of the backside power rail active PDN 530.

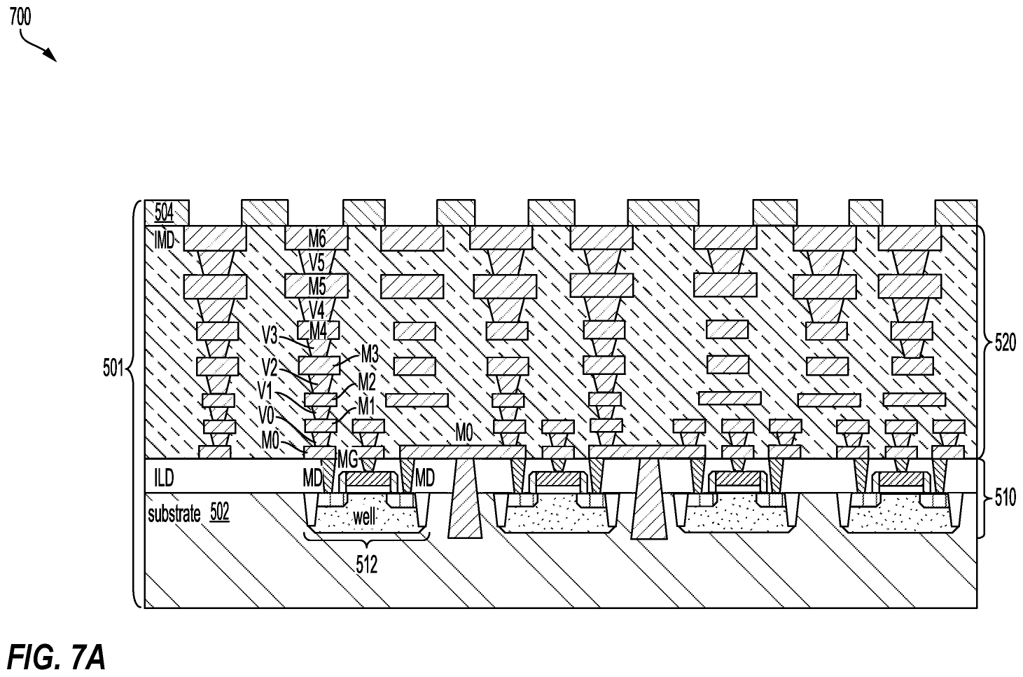

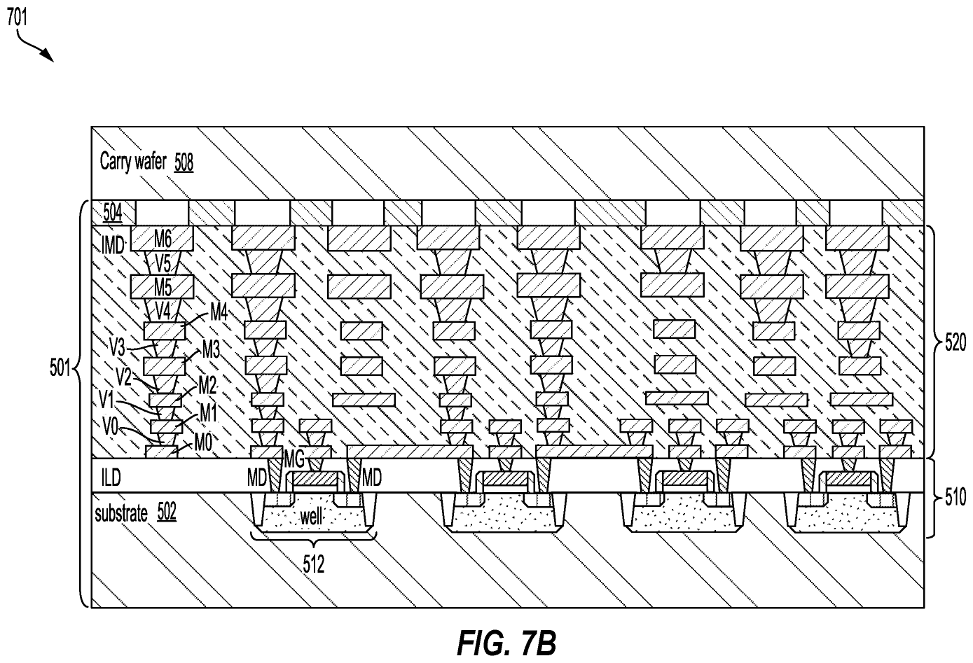

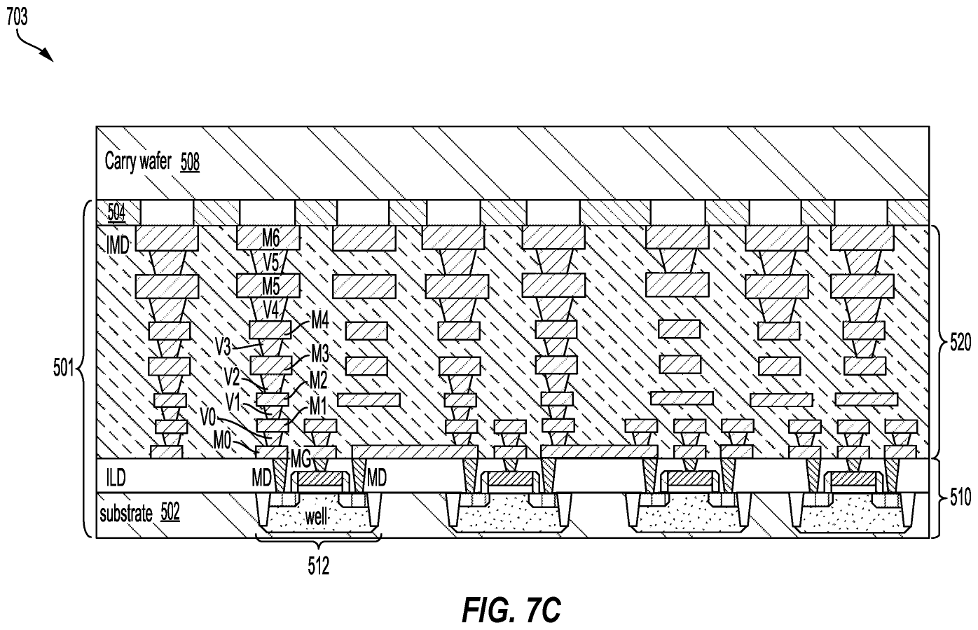

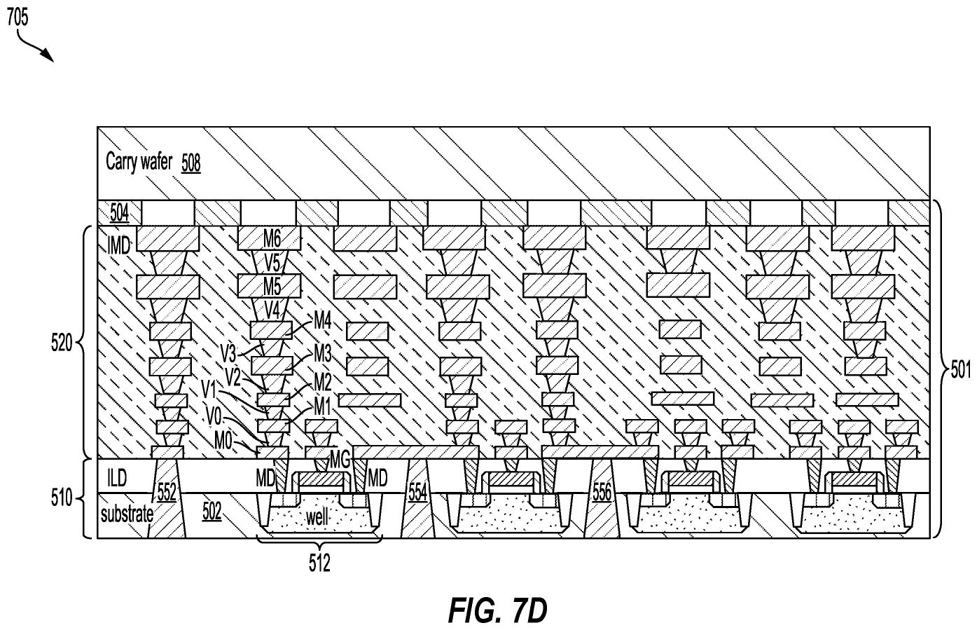

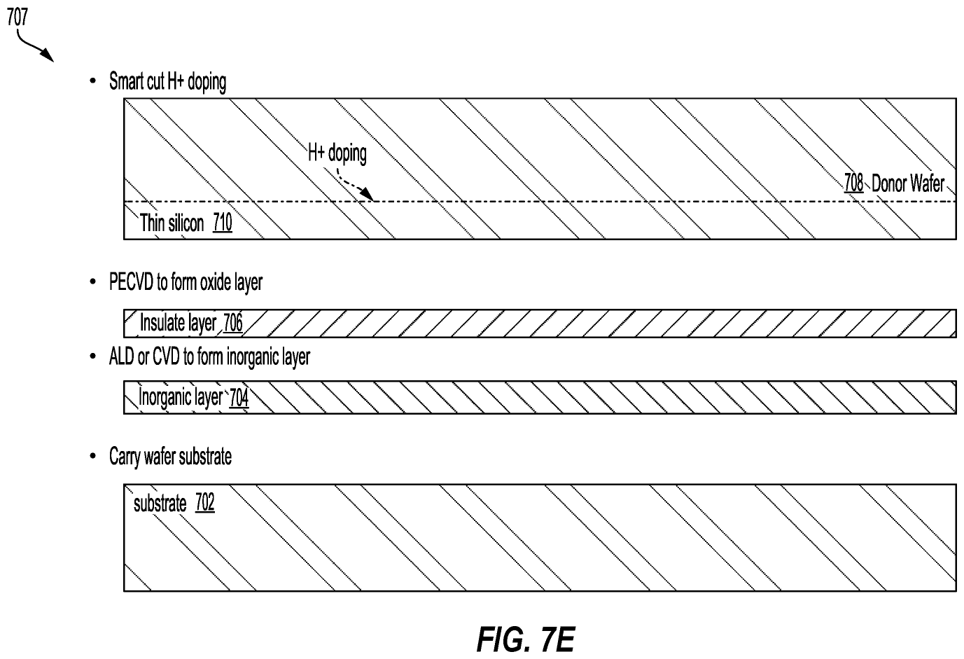

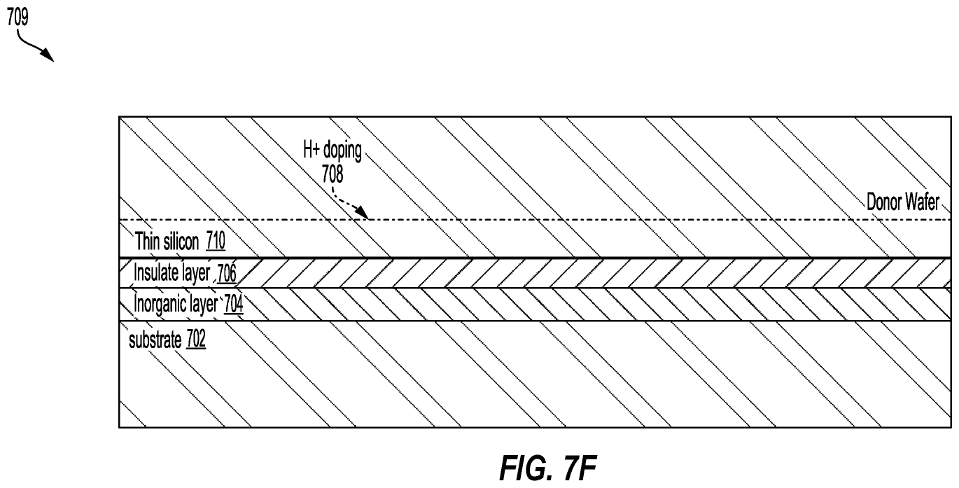

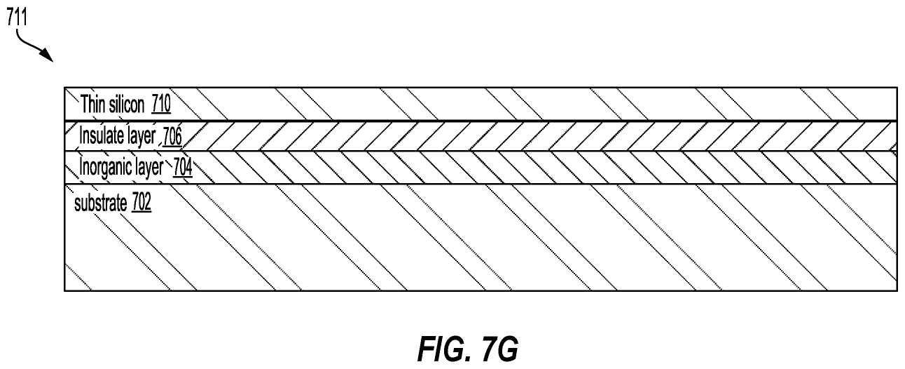

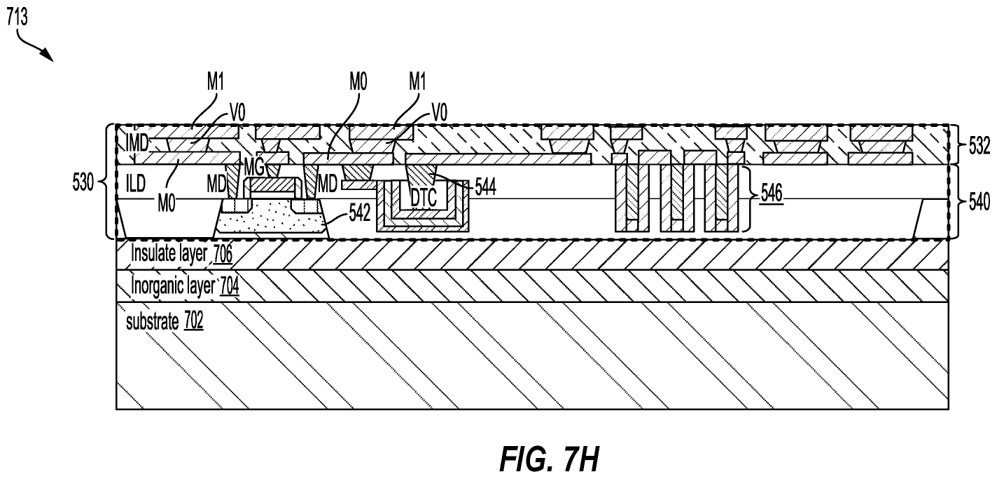

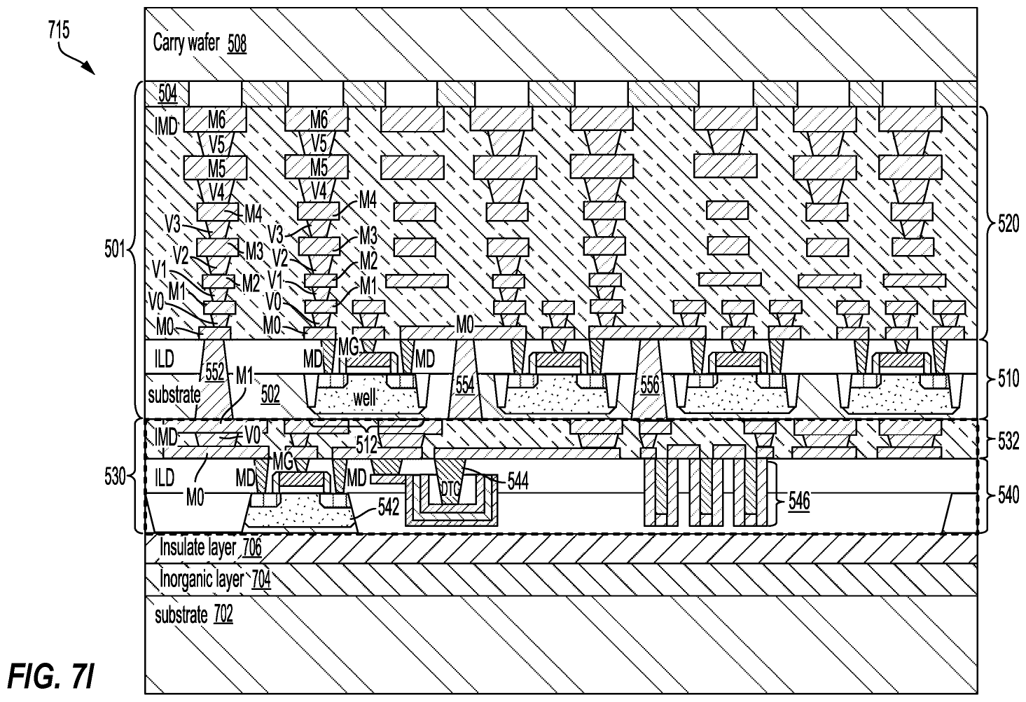

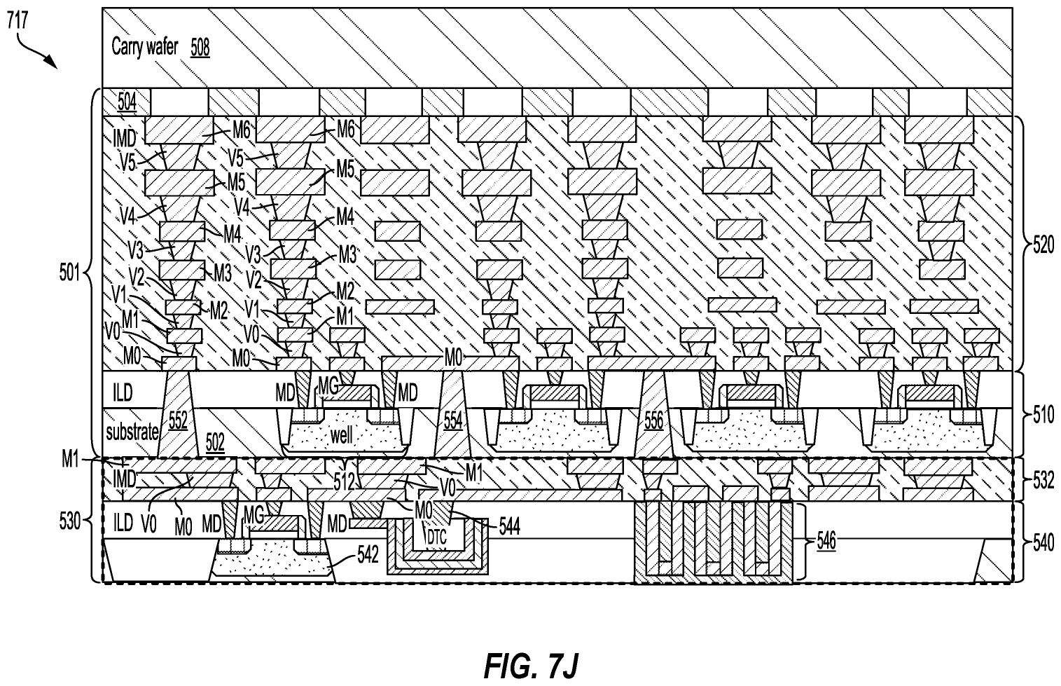

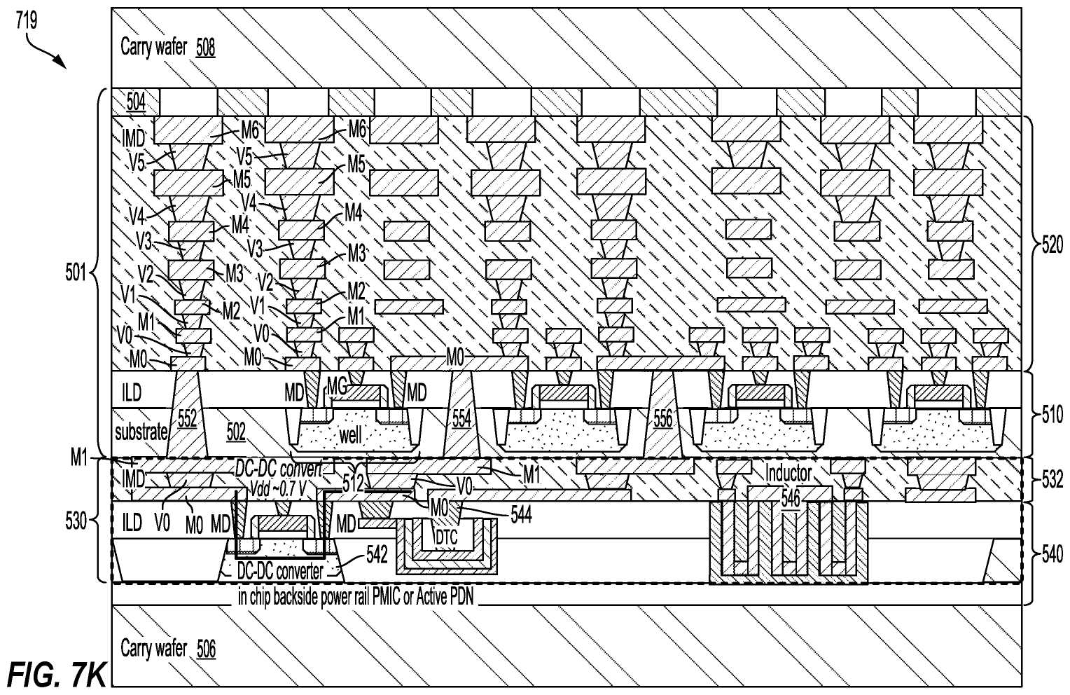

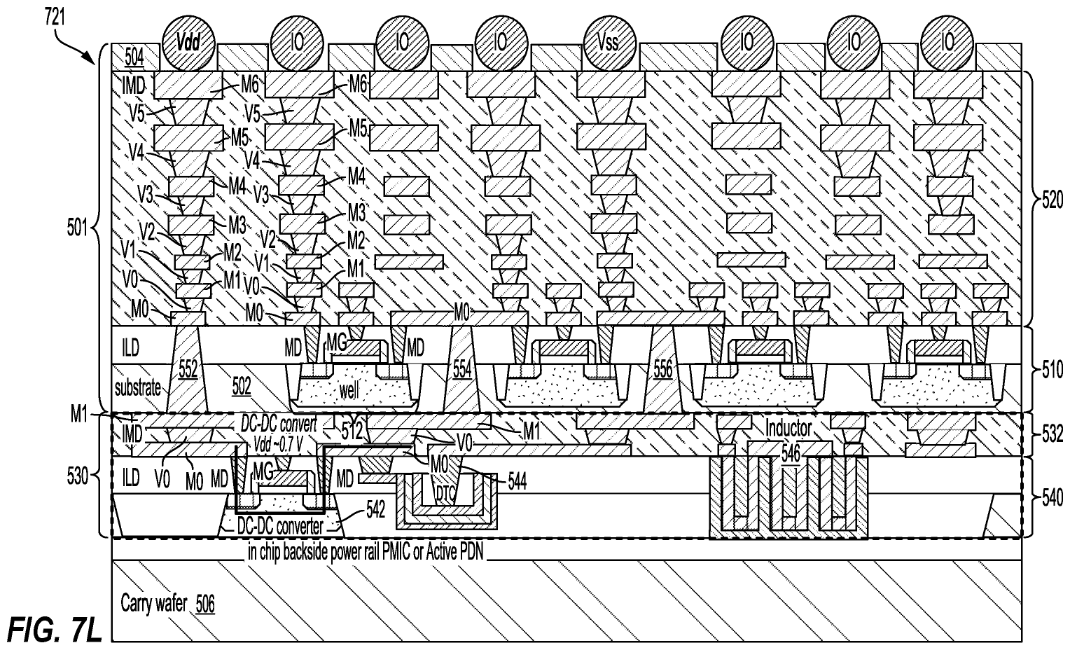

A process of fabricating a backside power rail active PDN is shown in FIGS. 7A-7L. FIGS. 7A-7L are cross-sectional diagrams illustrating a process for fabricating the IC 500 of FIG. 5, having the backside power rail active power distribution network (PDN) 530 integrated in the die 501, according to various aspects of the present disclosure.

FIG. 7A illustrates a first step 700 for fabricating an integrated circuit (IC) having a backside power rail active power distribution network (PDN) integrated in a die, according to various aspects of the present disclosure. In various aspects of the present disclosure, a start chip front-end-of-line (FEOL) device process is performed to form the active device layer 510 of the die 501. This FEOL process is followed by a middle-of-line (MOL)/back-end-of-line (BEOL) process to form the interconnect layer 520 of the die 501. The first step 700 terminates after forming an opening in the passivation layer 504. The first step 700 illustrates formation of the die 501, for example, as shown in FIG. 5, prior to integration of the backside power rail active PDN 530.

FIG. 7B illustrates a second step 701 for fabricating an integrated circuit (IC) having a backside power rail active power distribution network (PDN) integrated in a die, according to various aspects of the present disclosure. The second step 701 illustrates the securing of a carrier wafer 508 to the passivation layer 504 on the frontside of the die 501, for example, as shown in FIG. 5, prior to integration of the backside power rail active PDN 530.

FIG. 7C illustrates a third step 703 for fabricating an integrated circuit (IC) having a backside power rail active power distribution network (PDN) integrated in a die, according to various aspects of the present disclosure. The third step 703 illustrates the backside thinning of the substrate 502 of the die 501, for example, as shown in FIG. 5, to enable integration of the backside power rail active PDN 530.

FIG. 7D illustrates a fourth step 705 for fabricating an integrated circuit (IC) having a backside power rail active power distribution network (PDN) integrated in a die, according to various aspects of the present disclosure. The fourth step 705 illustrates backside via patterning and etching of the die 501 to expose a lower portion of the interconnect layer 520 (e.g., the M0 metal layer). Once exposed, a metal deposition process forms the via interconnect 552, the via interconnect 554, and the via interconnect 556, for example, as shown in FIG. 5, to enable integration of the backside power rail active PDN 530.

FIG. 7E illustrates a fifth step 707 for fabricating an integrated circuit (IC) having a backside power rail active power distribution network (PDN) integrated in a die, according to various aspects of the present disclosure. The fifth step 707 illustrates initial formation of a thin substrate 710 (e.g., silicon) to enable formation of a backside power rail active power distribution network (PDN), for example as shown in FIG. 5. FIG. 7E illustrates a carrier wafer substrate 702, an inorganic layer 704 formed using atomic layer deposition (ALD)/chemical vapor deposition (CVD), and an insulate layer 706. The insulate layer 706 may be an oxide layer formed using plasma enhanced CVD (PECVD). FIG. 7E also illustrates a smart cut doping (e.g., hydrogen (H+) doping) of a donor wafer 708 to enable formation of the thin substrate 710.

FIG. 7F illustrates a sixth step 709 for fabricating an integrated circuit (IC) having a backside power rail active power distribution network (PDN) integrated in a die, according to various aspects of the present disclosure. The sixth step 709 further illustrates initial formation of the thin substrate 710 to enable formation of a backside power rail active power distribution network (PDN), for example as shown in FIG. 5. FIG. 7F illustrates stacking and hydrogen bonding (e.g., O—H direct bond) of the carrier wafer substrate 702, the inorganic layer 704, the insulate layer 706, and the donor wafer 708. This stacking and bonding process enables a smart cut of the carrier wafer substrate 702 to form the thin substrate 710.

FIG. 7G illustrates a seventh step 711 for fabricating an integrated circuit (IC) having a backside power rail active power distribution network (PDN) integrated in a die, according to various aspects of the present disclosure. The seventh step 711 further illustrates formation of the thin substrate 710 to enable formation of a backside power rail active power distribution network (PDN), for example as shown in FIG. 5. FIG. 7G illustrates a smart cut and thermal splitting of the donor wafer 708. This is followed by thinning and cleaning to complete formation of the thin substrate 710, which may be a semiconductor-on-insulator (SOI) substrate.

FIG. 7H illustrates an eighth step 713 for fabricating an integrated circuit (IC) having a backside power rail active power distribution network (PDN) integrated in a die, according to various aspects of the present disclosure. The eighth step 713 illustrates formation of the backside power rail active power distribution network (PDN) 530, for example as shown in FIG. 5. FIG. 7G illustrates an SOI thin layer transfer (TLT) semiconductor front-end-of-line (FEOL) process to form the power switch 542 and the DTC 544 to provide an active DC-DC convertor/head switch/PMIC of the backside power rail active PDN 530. Additionally, a magnetic film is filled into an inductor space area to form the inductor 546 as a magnetic inductor to complete formation of the device layer 540. This FEOL process is followed by a middle-of-line (MOL)/back-end-of-line (BEOL) process to make routing and connection of the IMD layer 532.

FIG. 7I illustrates a ninth step 715 for fabricating an integrated circuit (IC) having a backside power rail active power distribution network (PDN) integrated in a die, according to various aspects of the present disclosure. The ninth step 715 illustrates a stacking and hydrogen bonding (e.g., O—H direct bond) of the backside power rail active PDN 530, including the carrier wafer substrate 702, the inorganic layer 704, and the insulate layer 706. This stacking and bonding process also includes a metal-to-metal (e.g., copper (Cu) to Cu) bonding of the M1 metal layer of the IMD layer 532 and the via interconnect 552, the via interconnect 554, and the via interconnect 556.

FIG. 7J illustrates a tenth step 717 for fabricating an integrated circuit (IC) having a backside power rail active power distribution network (PDN) integrated in a die, according to various aspects of the present disclosure. The tenth step 717 illustrates completion of the backside power rail active PDN 530. As shown in FIG. 7J, the carrier wafer substrate 702, the inorganic layer 704, and the insulate layer 706 are de-bonded from the backside power rail active PDN 530. Additionally, the inductor space area of the inductor 546 is opened and a magnetic material is deposited, which is followed by a chemical mechanical polish (CMP) process to complete formation of the inductor 546.

FIG. 7K illustrates an eleventh step 719 for fabricating an integrated circuit (IC) having a backside power rail active power distribution network (PDN) integrated in a die, according to various aspects of the present disclosure. The eleventh step 719 illustrates bonding of the carrier wafer 506 to the backside power rail active PDN 530. As shown in FIG. 7K, an additional interlayer dielectric (ILD) material may be deposited between the backside power rail active PDN 530 and the carrier wafer 506.

FIG. 7L illustrates a twelfth step 721 for fabricating an integrated circuit (IC) having a backside power rail active power distribution network (PDN) integrated in a die, according to various aspects of the present disclosure. The twelfth step 721 illustrates de-bonding of the carrier wafer 508 from the passivation layer 504. Once de-bonded, the Vdd ball, the Vss ball, and the IO balls are formed on the upper portion of the interconnect layer 520 of the die 501 to complete formation of the IC 500, including the backside power rail active PDN 530, for example, as shown in FIG. 5.

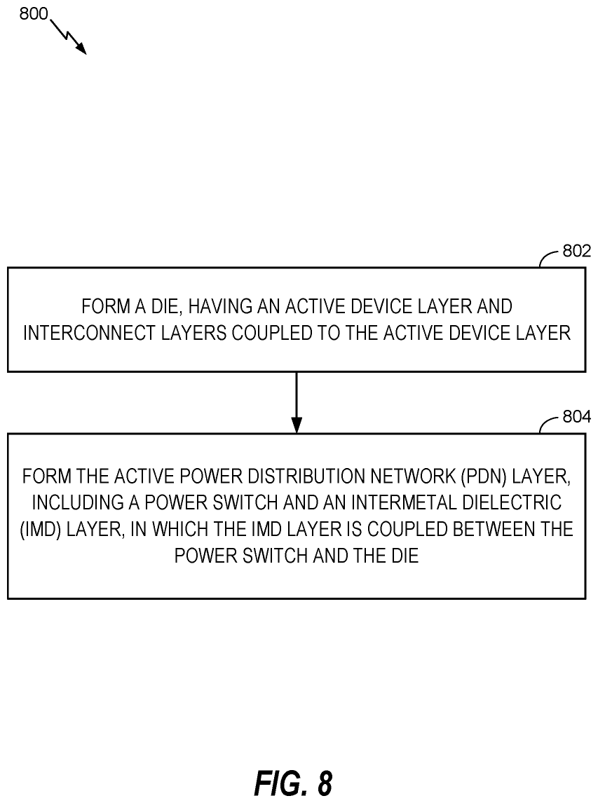

FIG. 8 is a process flow diagram illustrating a method for fabricating an active power distribution network (PDN) layer, according to various aspects of the present disclosure. The method 800 begins at block 802, in which a die is formed, the die having an active device layer and interconnect layers coupled to the active device layer. For example, as shown in FIG. 4A, the IC 400 includes a die 401, having an active device layer 410 and an interconnect layer 420 coupled to active devices 412 in a substrate 402 of the active device layer 410. In this example, the interconnect layer 420 includes middle-of-line (MOL) layers (M0, V0) coupled to the active devices 412 through metal-to-diffusion (MD) contacts and metal-to-gate (MG) contacts. Additionally, the interconnect layer 420 includes back-end-of-line (BEOL) metal layers (e.g., M1, V1, M2, V2, M3, V3, M4, V4, M5, V5, M6) coupled to the active devices 412 through the MOL layers (e.g., M0, V0), and the contacts (e.g., MD, MG).

At block 804, the active power distribution network (PDN) layer is formed, the PDN layer including a power switch and an intermetal dielectric (IMD) layer, in which the IMD layer is coupled between the power switch and the die. For example, as shown in FIG. 4A, an active power distribution network (PDN) 430 is integrated with the interconnect layer 420 on a frontside of the die 401. In this example, the active PDN 430 includes an intermetal dielectric (IMD) layer 432 on a device layer 440. Additionally, the active PDN 430 is bonded to the frontside of the die 401 using, for example, a metal to metal (e.g., copper Cu) hybrid bonding of a first metal (M1) layer of the IMD layer 432 and an M6 metal layer of the interconnect layer 420 at the backside of the die 401. In this example, an IO via interconnect 434 and an IO interconnect 436 extend through the device layer 440 of the active PDN 430 and couple IO pads supporting IO balls to zero metal (M0) layers of the IMD layer 432.

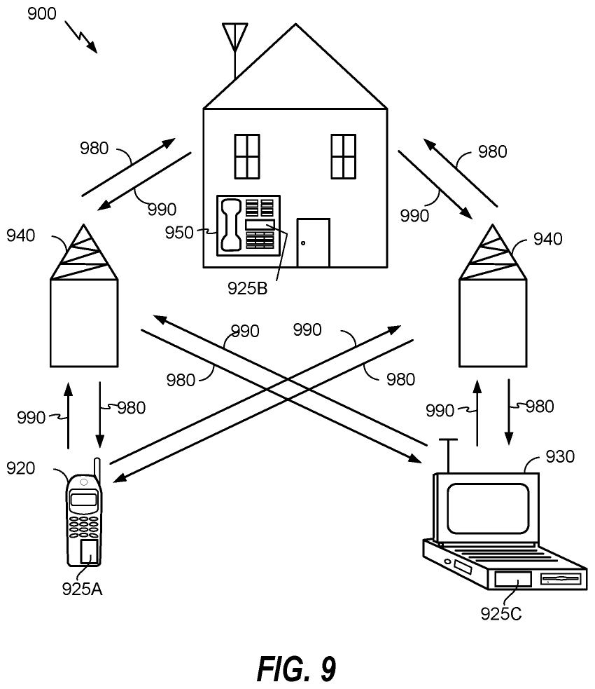

FIG. 9 is a block diagram showing an exemplary wireless communications system 900, in which an aspect of the present disclosure may be advantageously employed. For purposes of illustration, FIG. 9 shows three remote units 920, 930, and 950, and two base stations 940. It will be recognized that wireless communications systems may have many more remote units and base stations. Remote units 920, 930, and 950 include integrated circuit (IC) devices 925A, 925B, and 925C that include the disclosed advanced active PDN. It will be recognized that other devices may also include the disclosed advanced active PDN, such as the base stations, switching devices, and network equipment. FIG. 9 shows forward link signals 980 from the base stations 940 to the remote units 920, 930, and 950, and reverse link signals 990 from the remote units 920, 930, and 950 to the base stations 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 9 illustrates remote units according to the aspects of the present disclosure, the disclosure is not limited to these exemplary illustrated units. Aspects of the present disclosure may be suitably employed in many devices, which include the disclosed advanced active PDN.

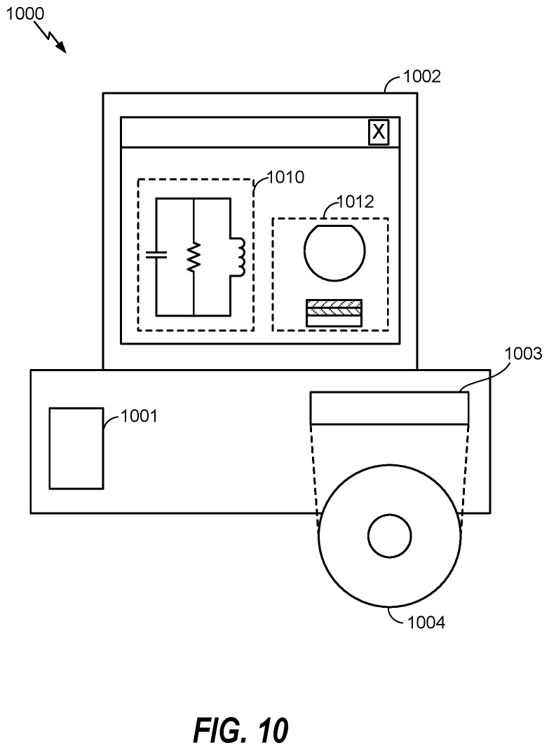

FIG. 10 is a block diagram illustrating a design workstation 1000 used for circuit, layout, and logic design of a semiconductor component, such as the advanced active PDN disclosed above. The design workstation 1000 includes a hard disk 1001 containing operating system software, support files, and design software such as Cadence or OrCAD. The design workstation 1000 also includes a display 1002 to facilitate design of a circuit 1010 or a semiconductor component 1012, such as the advanced active PDN. A storage medium 1004 is provided for tangibly storing the design of the circuit 1010 or the semiconductor component 1012 (e.g., the advanced active PDN). The design of the circuit 1010 or the semiconductor component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the semiconductor component 1012 by decreasing the number of processes for designing semiconductor wafers.

Implementation examples are described in the following numbered clauses:
1. An integrated circuit (IC), comprising:
a die, comprising an active device layer and interconnect layers coupled to the active device layer; and
an active power distribution network (PDN) layer, including a power switch and an intermetal dielectric (IMD) layer, in which the IMD metal layer is coupled between the power switch and the die.
2. The IC of claim 1, in which the active PDN layer is on a backside of the die.
3. The IC of claim 1, in which the active PDN layer is on a frontside of the die.
4. The IC of claim 1, further comprising a via interconnect, extending through the active device layer, and coupling a first metal (M1) layer of the interconnect layers to an M1 metal layer of the IMD layer of the active PDN layer on a backside of the die.
5. The IC of claim 1, further comprising a via interconnect, extending through the active device layer, and coupling a zero metal (M0) layer of the interconnect layers to an M1 metal layer of the IMD layer of the active PDN layer on a backside of the die.
6. The IC of claim 1, further comprising micro-bumps to couple the interconnect layers of the die to a first metal (M1) layer of the IMD layer of the active PDN layer on a frontside of the die.
7. The IC of claim 1, further comprising back-end-of-line (BEOL) metal layers of the interconnect layers coupled to an M1 metal layer of the IMD layer of the active PDN layer on a frontside of the die.
8. The IC of any of clauses 1-7, in which the power switch comprises a direct current (DC) to DC (DC-DC) converter.
9. The IC of clause 8, in which the active PDN layer further comprises:
a deep trench capacitor (DTC) coupled to the DC-DC converter; and
a magnetic inductor coupled to the DTC.
10. The IC of any of clauses 1-9, in which the IC comprises a system-on-chip.
11. A method for fabricating an integrated circuit (IC) having an active power distribution network (PDN) layer, comprising:
forming a die, having an active device layer and interconnect layers coupled to the active device layer; and
forming the active power distribution network (PDN) layer, including a power switch and an intermetal dielectric (IMD) layer, in which the IMD layer is coupled between the power switch and the die.
12. The method of clause 11, in which the active PDN layer is on a backside of the die.
13. The method of clause 11, in which the active PDN layer is on a frontside of the die.
14. The method of any of clauses 11-13, further comprising forming a via interconnect, extending through the active device layer, and coupling a first metal (M1) layer of the interconnect layers to an M1 metal layer of the IMD layer of the active PDN layer on a backside of the die.
15. The method of any of clauses 11-14, further comprising forming a via interconnect, extending through the active device layer, and coupling a zero metal (M0) layer of the interconnect layers to an M1 metal layer of the IMD layer of the active PDN layer on a backside of the die.
16. The method of any of clauses 11-15, further comprising forming micro-bumps to couple the interconnect layers of the die to a first metal (M1) layer of the IMD layer of the active PDN layer on a frontside of the die.
17. The method of any of clauses 11-16, further comprising forming back-end-of-line (BEOL) metal layers of the interconnect layers coupled to an M1 metal layer of the IMD layer of the active PDN layer on a frontside of the die.
18. The method of any of clauses 11-17, in which the power switch comprises a direct current (DC) to DC (DC-DC) converter.
19. The method of clause 18, in which forming the active PDN layer further comprises:
forming a deep trench capacitor (DTC) coupled to the DC-DC converter; and
forming a magnetic inductor coupled to the DTC.
20. The method of any of clauses 11-19, in which the IC comprises a system-on-chip.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the particular configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described but is to be accorded the widest scope consistent with the principles and novel features disclosed.

What is claimed is:

1. An integrated circuit (IC), comprising:
a die, comprising an active device layer and interconnect layers coupled to the active device layer; and
an active power distribution network (PDN) layer, including a power switch and an intermetal dielectric (IMD) layer, in which the IMD metal layer is coupled between the power switch and the die.

2. The IC of claim 1, in which the active PDN layer is on a backside of the die.

3. The IC of claim 1, in which the active PDN layer is on a frontside of the die.

4. The IC of claim 1, further comprising a via interconnect, extending through the active device layer, and coupling a first metal (M1) layer of the interconnect layers to an M1 metal layer of the IMD layer of the active PDN layer on a backside of the die.

5. The IC of claim 1, further comprising a via interconnect, extending through the active device layer, and coupling a zero metal (M0) layer of the interconnect layers to an M1 metal layer of the IMD layer of the active PDN layer on a backside of the die.

6. The IC of claim 1, further comprising micro-bumps to couple the interconnect layers of the die to a first metal (M1) layer of the IMD layer of the active PDN layer on a frontside of the die.

7. The IC of claim 1, further comprising back-end-of-line (BEOL) metal layers of the interconnect layers coupled to an M1 metal layer of the IMD layer of the active PDN layer on a frontside of the die.

8. The IC of claim 1, in which the power switch comprises a direct current (DC) to DC (DC-DC) converter.

9. The IC of claim 8, in which the active PDN layer further comprises:
a deep trench capacitor (DTC) coupled to the DC-DC converter; and
a magnetic inductor coupled to the DTC.

10. The IC of claim 1, in which the IC comprises a system-on-chip.

11. A method for fabricating an integrated circuit (IC) having an active power distribution network (PDN) layer, comprising:
forming a die, having an active device layer and interconnect layers coupled to the active device layer; and
forming the active power distribution network (PDN) layer, including a power switch and an intermetal dielectric (IMD) layer, in which the IMD layer is coupled between the power switch and the die.

12. The method of claim 11, in which the active PDN layer is on a backside of the die.

13. The method of claim 11, in which the active PDN layer is on a frontside of the die.

14. The method of claim 11, further comprising forming a via interconnect, extending through the active device layer, and coupling a first metal (M1) layer of the interconnect layers to an M1 metal layer of the IMD layer of the active PDN layer on a backside of the die.

15. The method of claim 11, further comprising forming a via interconnect, extending through the active device layer, and coupling a zero metal (M0) layer of the interconnect layers to an M1 metal layer of the IMD layer of the active PDN layer on a backside of the die.

16. The method of claim 11, further comprising forming micro-bumps to couple the interconnect layers of the die to a first metal (M1) layer of the IMD layer of the active PDN layer on a frontside of the die.

17. The method of claim 11, further comprising forming back-end-of-line (BEOL) metal layers of the interconnect layers coupled to an M1 metal layer of the IMD layer of the active PDN layer on a frontside of the die.

18. The method of claim 11, in which the power switch comprises a direct current (DC) to DC (DC-DC) converter.

19. The method of claim 18, in which forming the active PDN layer further comprises:
forming a deep trench capacitor (DTC) coupled to the DC-DC converter; and
forming a magnetic inductor coupled to the DTC.

20. The method of claim 11, in which the IC comprises a system-on-chip.
